(19) United States
(12) Patent Application Publication
(10) Pub. No.: US 2006/0274508 A1
(43) Pub. Date: Dec. 7, 2006

(54) Computer rack mounting system

(75) Inventors: Phillip H. LaRiviere, Woonsocket, RI (US); Takeyoshi Horie, Lunenburg, MA (US); Vincent T. Curran, Walpole, MA (US); Brian Herrick, Lunenburg, MA (US)

Correspondence Address: KIRKPATRICK & LOCKHART NICHOLSON GRAHAM LLP, STATE STREET FINANCIAL CENTER, ONE LINCOLN STREET, BOSTON, MA, 02111-2950, US

(73) Assignee: Stratus Technologies Bermuda Ltd., Hamilton (BM)

(21) Appl. No.: 11/145,784

(22) Filed: Jun. 6, 2005

(51) Int. Cl. H05K 7/16

(52) U.S. Cl. 361/727

(57) ABSTRACT

The invention relates to computer systems, and more specifically to a method and apparatus for inserting and storing server units in a rack-mounted computer. In one embodiment, the system includes a cabinet comprising a plurality of rails. The system also includes a rack that is coupled to the rails for receiving the server units. A mounting latch is pivotally coupled to the server unit, the mounting latch including a fastener that is securable to the rails.

### TECHNICAL FIELD

The invention relates generally to computer hardware systems and more specifically to a method and apparatus for inserting and storing server units in a rack-mounted computer.

### BACKGROUND OF THE INVENTION

A rack-mounted computer system is a computer system that is built in a frame or cabinet. The frame or cabinet typically has a standard width (e.g. 19 inches or 23 inches) and can have space for one or more server units, such as motherboards. The server units are typically inserted into the rack-mounted computer system until a connector on the server unit connects, or mates, with a connector on the backplane of the rack-mounted computer system.

Insertion of a server unit into the computer system can potentially damage the delicate connectors on both the server unit and the backplane. Damage may occur during the installation process because the server units tend to be bulky in shape, which makes it difficult to carefully maneuver and position the server units into the computer system. A rapid or inaccurate insertion of the server unit can lead to the inoperability of one or more pins of the connectors of each component. This may lead to the inoperability of the connector for the server unit and/or the destruction of the connector on the backplane.

Once the server unit is installed in the computer system, there is often a further need to ensure that the server unit remains aligned and secure in the computer system. Misalignment may occur, for example, during the shipment/movement of the computer system or as a result of the system being inadvertently bumped. If the server unit is not aligned properly in the computer system, the connectors on one or both of the server unit and the backplane may be damaged, and the server unit may become inoperable in the computer system.

Therefore, a need exists to simplify the procedure of inserting server units into a rack-mounted computer system while simultaneously reducing the exposure of the connectors of each device to potential damage. A need also exists to reduce the potential of server units becoming misaligned once they are installed in the computer system.

### SUMMARY OF THE INVENTION

In general, the invention relates to a computer hardware system and more specifically to a method and apparatus for inserting and storing server units in a rack-mounted computer system. The rack-mounted computer system includes a rack that is mounted in a cabinet, and server units that may be inserted into the rack. The system also includes guide members that aid in the insertion of the server units into the rack, while reducing the potential for an inaccurate insertion of the server units. One advantage of the invention is that the server units are more securely mounted in the rack-mounted computer system, since the server units are secured to both the rack and the cabinet. Another advantage of the invention is that the server units may be easily replaced in the event that a server unit requires repair.

In one aspect, the invention relates to a system for mounting a server unit. The system includes a cabinet that includes a plurality of rails and a rack for receiving the server unit. The rack is couplable to the rails. The system also includes a mounting latch that is pivotally couplable to the server unit. The mounting latch also includes a fastener that is securable to a rail.

In one embodiment, the rack further includes a plurality of guides for aligning the server unit in the rack. The guides may include pins and/or a horizontal plate disposed between sidewalls of the rack. The rack may also include adjustable sidewalls. In another embodiment, the mounting latch includes a spring that biases an end of the mounting latch towards a front surface of the rack, the end acting as a bumper. In an alternative embodiment, a curved surface of the mounting latch engages a pin disposed on a front surface of the rack.

In another embodiment of the system, the plurality of rails include front and rear rails, where the front rails are longitudinally spaced from the rear rails. In yet another embodiment, the server unit includes a plurality of baffles to control airflow within the server unit. The baffles may control at least one of the direction and the amount of the airflow directed to a voltage regulation module.

In another aspect, the invention relates to a mounting clip for securing a component into a rail. The mounting clip includes a body and a first, second, and third spring extending longitudinally from the body, each spring including a curved portion. The first spring is oriented in a first direction relative to the body, the second spring is oriented in a second direction relative to the body, and the third spring is rotated in a third direction relative to the body. When secured to the rail, the mounting clip prevents motion of the component horizontally and vertically.

In another aspect, the invention relates to a mounting latch for fastening a server unit to a cabinet rail. The mounting latch includes a body pivotally couplable to a server unit, where the body includes a fastener engageable with the cabinet rail. In one embodiment, the body further includes a curved surface rotatably engageable with a rack, the rack couplable to the cabinet rail. The body may also include a pivoting member and a bracket couplable to the server unit. In another embodiment, the body includes a locking member disposed between the pivoting member and the bracket to prevent the pivoting member from rotating relative to the server unit. The locking member may include a protrusion disposed on the pivoting member for mating with a groove disposed in the bracket. Alternatively, the locking member may include a groove disposed in the pivoting member for mating with a protrusion disposed on the bracket. The mounting latch may also include a spring to bias an end of the mounting latch towards a front surface of the rack, the end of the mounting latch acting as a bumper. In various embodiments, the fastener includes a threaded portion for engaging the cabinet rail. Alternatively, the fastener may include a slotted head for receiving a tool.

These and other objects, along with advantages and features of the present invention herein disclosed, will become apparent through reference to the following description, the accompanying drawings, and the claims. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis generally being placed upon illustrating the principles of the invention. In the following description, various embodiments of the present invention are described with reference to the following drawings.

FIG. 1 is a perspective view of an embodiment of a rack-mounted computer system for installing and removing server units.

FIG. 2 is an exploded perspective view of another embodiment of a rack-mounted computer system having a rack with adjustable sidewalls.

FIG. 3 is a perspective view of the rack-mounted computer system of FIG. 1 with server units loaded into the system.

FIG. 4 is a perspective view of one embodiment of a backplane for use with the rack-mounted computer system of FIG. 1.

FIG. 5 is a perspective view of another embodiment of a rack-mounted computer system having a mounting latch.

FIG. 6 is a perspective view of the rack-mounted computer system of FIG. 5 with the mounting latch shown in a closed position.

FIG. 7A is a perspective view of an embodiment of cover plates for attachment to a rack-mounted computer system.

FIG. 7B is a front view of a cover plate of FIG. 7A.

FIG. 7C is a top view of the cover plate of FIG. 7B.

FIG. 7D is a bottom view of the cover plate of FIG. 7B.

FIG. 7E is a right end view of the cover plate of FIG. 7B.

FIG. 7F is a left end view of the cover plate of FIG. 7B.

FIG. 7G is a perspective view of an embodiment of a backer plate for mounting with the cover plates of FIG. 7A.

FIG. 7H is a perspective view of an embodiment of a 1 U cover plate.

FIG. 71 is a back view of the cover plate of FIG. 7H.

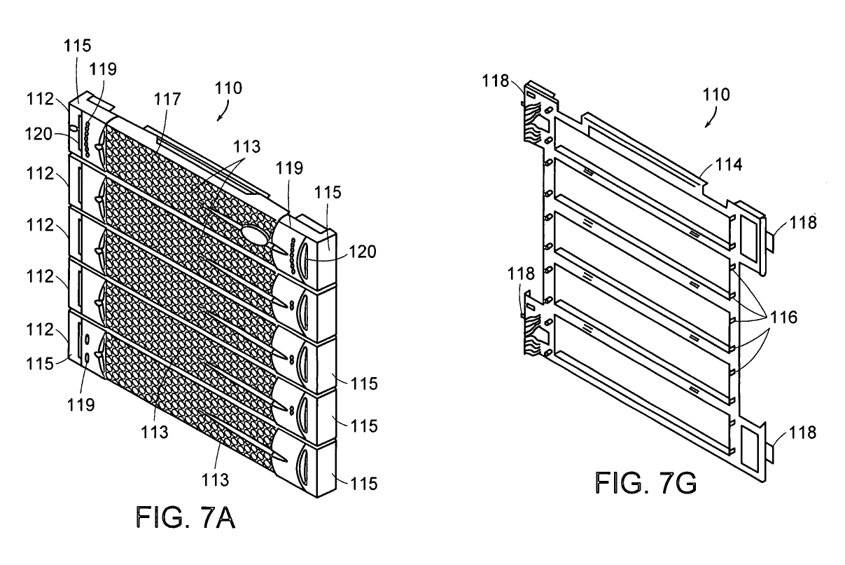

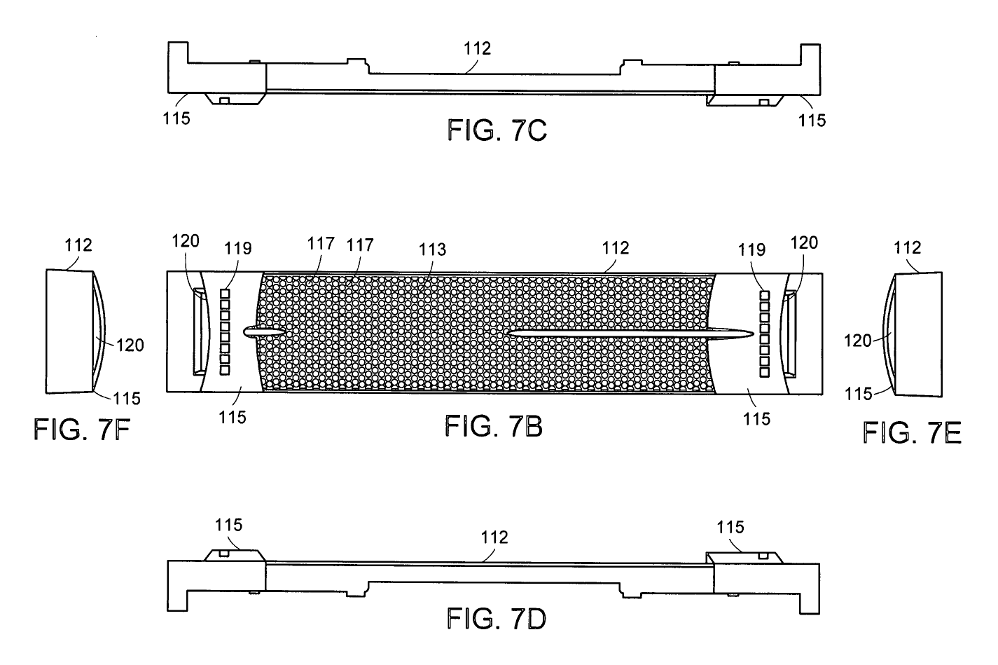

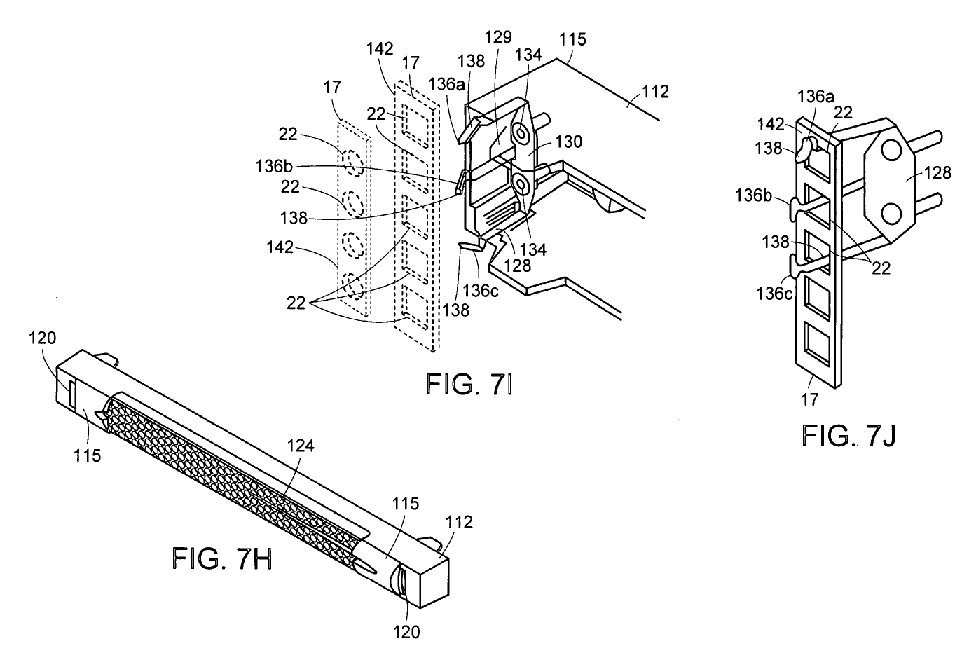

FIG. 7J is a back view of the cover plate of FIG. 7H secured to a rail.

FIG. 8A is a perspective view of an embodiment of a cover plate.

FIG. 8B is a perspective view of a 1 U cover plate.

FIG. 9 is a perspective view of an embodiment of a rack-mounted computer system for installing and removing server units.

FIG. 10 is a perspective view of the rack-mounted computer system of FIG. 9 without any server units loaded into the system.

FIG. 11 is an exploded perspective view of a backplane for use with the rack-mounted computer system of FIG. 9.

FIG. 12A is a perspective view of an embodiment of a pedestal storage system for vertically mounting server units, the pedestal storage system illustrated in a vertical storage position.

FIGS. 12B-12C are perspective views of embodiments of the pedestal storage system of FIG. 12A, the pedestal storage system illustrated in a horizontal storage position.

FIG. 13 is a perspective view of an embodiment of cover plates for use with the pedestal storage system of FIG. 12A.

FIG. 14A is a perspective view of one embodiment of baffle blockers mounted in a server unit.

FIG. 14B is a front view of the server unit of FIG. 14A.

### DETAILED DESCRIPTION

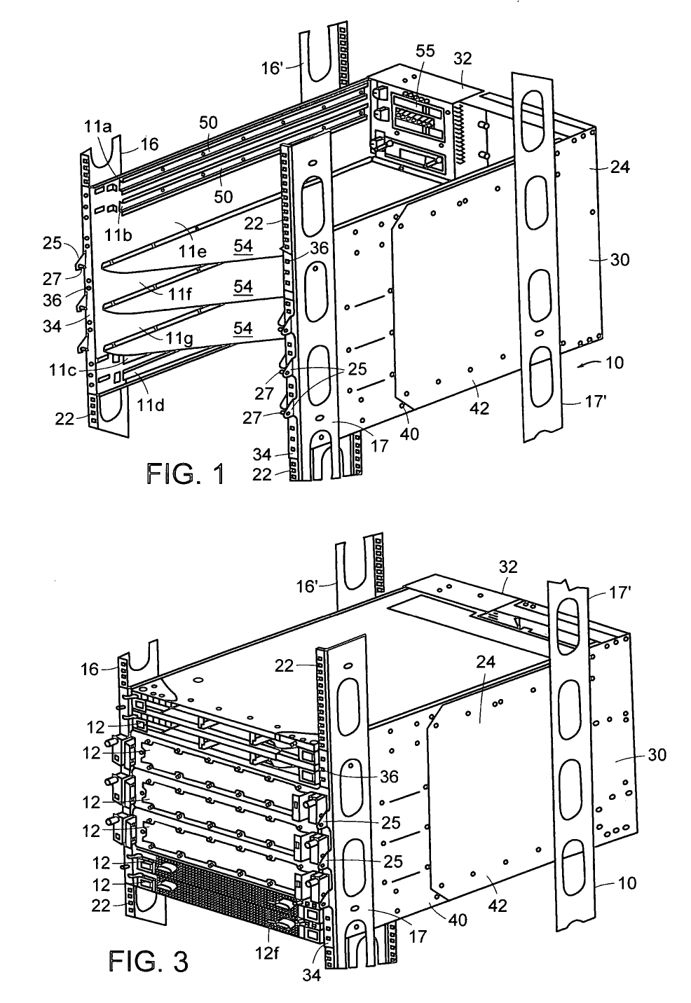

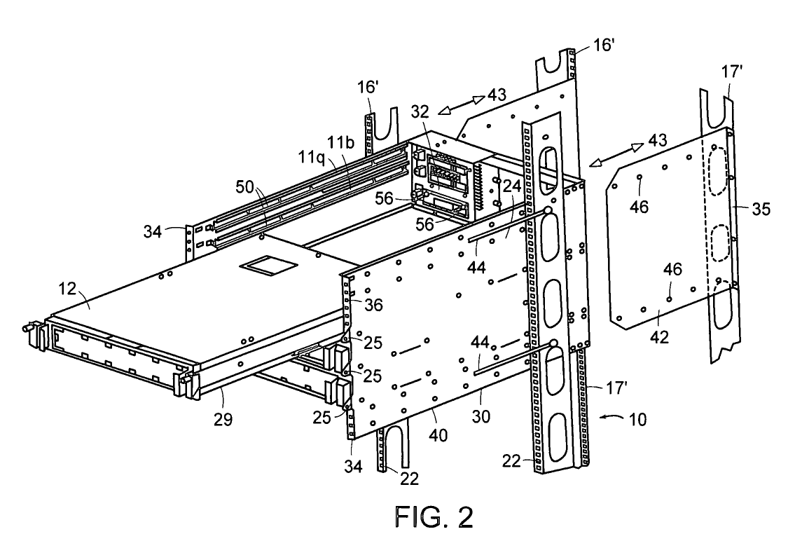

Referring to FIGS. 1-3, the invention relates to the installation and removal of server units 12 from a rack 24 that is securable to a cabinet 10. The rack 24 includes a plurality of slots 11a-11g (generally 11) that are 1 U in height (i.e. slots 11a, 11b, 11c, and 11d) and 2 U in height (i.e. slots 11e, 11f, and 11g). In general, a “U” as used above is a standard unit of measure used in the computer industry for designating the height in computer enclosures and cabinets. In one embodiment, a U equals 1.75 inches. For example, a 4 U cabinet is 7 inches high and a 40 U cabinet is 70 inches high. It should be noted that the cabinet 10 can be any reasonable height and can consequently connect to any number of server units 12. Additionally, the cabinet 10 may be able to accept server units 12 having any reasonable height (e.g., 1 U, 2 U, 3 U, 4 U). The slots that are 1 U in height accept I/O boards (i.e. server units 12) that are 1 U in height, and the slots that are 2 U in height accept CPU boards (i.e. server units 12) that are 2 U in height. In FIG. 1, the rack 24 is illustrated without any server units 12 mounted in the slots I1. In FIG. 2, the rack 24 is shown with slots 11e, 11f, and 11g loaded with server units 12 that are each 2 U in height. In FIG. 3, the rack 24 is shown with each slot 11 loaded with a server unit 12.

In one embodiment, the server units 12 are each 1 U rack-mounted motherboards. In general, a rack-mounted motherboard is a motherboard that is built for installation in a metal frame or cabinet of standard width (typically 19 inches or 23 inches) and mounting arrangements.

Referring again to FIG. 1, the cabinet 10 is shown in greater detail. Generally, the cabinet 10 includes a pair of front rails 16, 17, and a pair of rear rails 16′, 17′ that are vertically mounted and fixed in position relative to each other. Optionally, an enclosure (not shown) with front and rear access panels to access the server units 12 may be coupled to the rails 16, 16′, 17, 17′. The enclosure may be made from metals, plastics, or any other suitable material. Together, the front rails 16, 17, and the rear rails 16′, 17′ support the rack 24 when the rack 24 is mounted into the cabinet 10. Cabinets 10 are available from suppliers like Rittal Corporation (Springfield, Ohio) and are custom ordered to provide sufficient strength to support the rack 24 and the server units 12. For instance, a 38 U cabinet 10 may be ordered with a 1500 lbs pay load rating so that the cabinet 10 supports up to 1500 lbs of equipment. Similarly, a 24 U cabinet 10 may be ordered with a 1200 lbs payload rating to support up to 1200 lbs of equipment.

Each rail 16, 16′, 17, 17′ includes a plurality of apertures 22. In the illustrated embodiment, the apertures 22 are square and are shown as being equidistantly spaced from each other. In other embodiments, however, the apertures 22 may be circular, oval, or any other desired shape and the distance between the apertures 22 may vary.

Referring again to FIGS. 1-3, the rack 24 is shown coupled to the rails 16, 16′, 17, 17′. The rack 24 may be made from metals such as aluminum, re-enforced plastics, or any other suitable material that does not deform during use. With reference to FIG. 2, the rack 24 includes right and left adjustable sidewalls 30. Each sidewall 30 includes a front wall 40 and a rear wall 42, which couple together as will be described.

Referring to FIG. 2, the front wall 40 includes a flange 34 that is substantially perpendicular to the remainder of the front wall 40. Similarly, the rear wall 42 includes a flange 35 that is substantially perpendicular to the remainder of the rear wall 42. The flanges 34, 35 of each front and rear wall 40, 42 include a plurality of apertures 36 that may be formed in a punching operation. In the illustrated embodiment, the apertures 36 are oval and are shown as being equidistantly spaced from each other. In other embodiments, however, the apertures 36 may be square, circular, or any other desired shape. The distance between the apertures 36 may also vary.

The flange 34 of each front wall 40 additionally includes brackets 25 that extend outwardly from the flanges 34. As shown in more detail in FIG. 5, each bracket 25 includes a cylindrical guide/stop pin 27 integrally formed with the bracket 25 that extends from the bracket 25 in a direction parallel to the flange 34. In alternative embodiments, the guide/stop pin 27 is a separate component secured to the bracket 25 and is any desired shape. The guide/stop pins 27 help locate and secure the server units 12 in the rack 24 as described below.

Referring again to FIG. 2, the sidewalls 30 of the rack 24 are adjustable to accommodate different spacing between the front rails 16, 17 and rear rails 16′, 17′ of the cabinet 10. For instance, the rear wall 42 may be positioned relative to the front wall 40 in the direction of arrow 43 to accommodate different spacing between the front rails 16, 17 and rear rails 16′, 17′.

To assemble the front walls 40 and rear walls 42 of the rack 24, a user first couples the rear walls 42 to the back rails 16′, 17′ of the rack 24. In one embodiment, to couple the rear walls 42 to the back rails 16′, 17′, a user aligns the apertures 36 disposed in the flanges 35 of the rear walls 42 with the apertures 22 disposed in the rails 16′, 17′. The user then inserts pinning hardware through the aligned apertures 22, 36 to firmly secure the rear walls 42 to the back rails 16′, 17′. Similarly, while ensuring that the front walls 40 and the rear walls 42 are vertically aligned, a user couples the front walls 40 to the front rails 16, 17.

Referring to FIG. 2, once the front walls 42 are coupled to the front rails 16, 17, and the rear walls 42 are coupled to the rear rails 16′, 17′, as described above, a slotted key 44 disposed in each front wall 40 aligns with apertures 46 disposed in each rear wall 40. Since the apertures 46 may align anywhere along the slotted key 44, the rack 24 may accommodate a variety of cabinets 10 in which the spacing between the front rails 16, 17 and the rear rails 16′, 17′ varies. In one embodiment, pinning hardware, such as flat head screws securable to nuts, is inserted through the apertures 46 and the slotted keys 44 to firmly secure the front walls 40 and the rear walls 42. In an alternative embodiment, the front walls 40 are coupled to the rear walls 42 by rivets. Generally, any fastening mechanism desired may be used to couple the walls 40, 42, and the above examples are for illustration purposes only.

Referring to FIGS. 1-2, the rack 24 includes guide features that help align the server units 12 with the rack 24. For instance, in the illustrated embodiment, slots 11a-11d include mounting rails 50 that a server unit 12 can slide along as a server unit 12 is guided into the rack 24. In another embodiment, a server unit 12 may slide over rollers that are mounted to the sidewalls 30 in place of the mounting rails 50 (or that are used in combination with the mounting rails 50). In the illustrated embodiment, the mounting rails 50 receive server units 12 that are each 1 U in height. In alternative embodiments, the mounting rails 50 may receive server units 12 with a different height.

As a further guide to help align the server units 12 in the rack 24, horizontal plates 54 may be mounted between the sidewalls 30. When secured to the sidewalls 30, the horizontal plates 54 act as stiffening members to provide torsional rigidity to the rack 24. The plates 54 may be secured to the sidewalls 30 by rivets, and the plates 54 can be made of any desired material, such as aluminum, or any other metal. In use, each plate 54 supports a bottom surface 29 of the server unit 12 both during and after the insertion of the server unit 12 into the rack 24. In the illustrated embodiment, each horizontal plate 54 supports a server unit that is 2 U in height. In other embodiments, the horizontal plates 54 may be used to support server units 12 with a height other than 2 U. The mounting rails 50 and the horizontal plates 54 simplify the process of installing server units 12 into the rack 24 by aligning the server units 12 with the rack 24, while simultaneously supporting the mass of the server units 12.

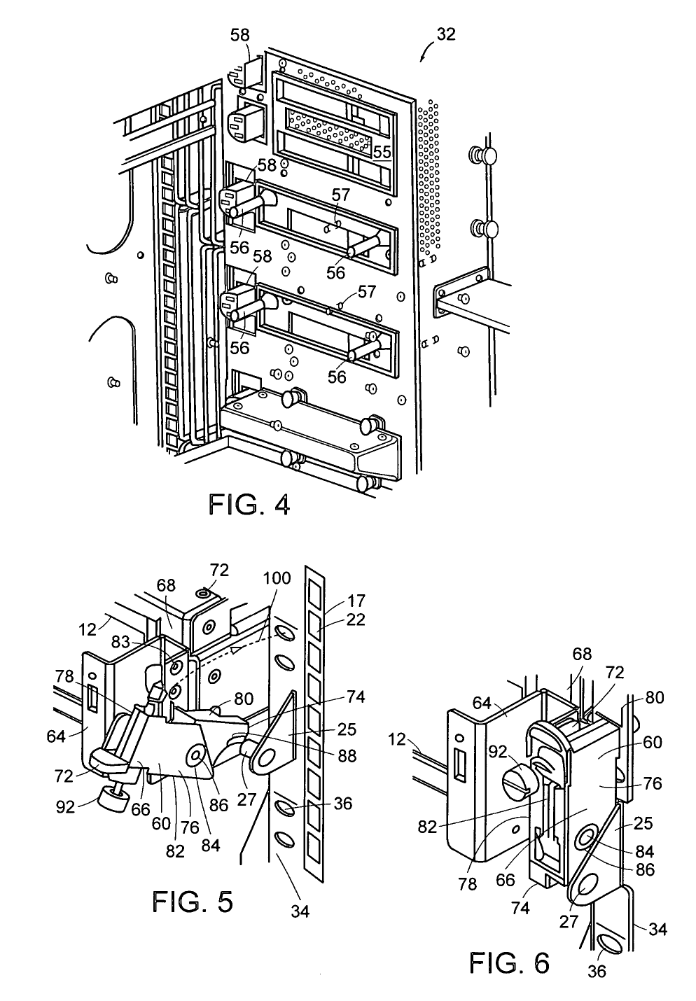

Referring to FIG. 4, a backplane 32 of the rack 24 is illustrated. In general, a backplane is a circuit board or framework that supports other circuit boards, devices, and the interconnections among devices, and provides power and data signals to supported devices. For example, some backplanes include a connector interface. A connector interface is an interface external to the server units 12 that provides a connection to an external network via, for example, an RJ-45 connector or coaxial cable connection. Similarly, the external connector interface may connect to an external modem and thus provides a network connection to the internet. The connector interface can also connect to one or more peripheral devices, such as a keyboard or mouse via, for example, a DB-9 connector, a DB-25 connector, or a USB port.

In addition to providing access to external devices, the backplane 32 may also increase the computing power of the server units 12. For instance, the server units 12 may have expansion cards plugged into sockets of the backplane 32 that increase the capabilities of the server unit 12. Backplanes are often described by those skilled in the art as being either “active” or “passive”. Active backplanes contain, in addition to the sockets, logical circuitry that performs computing functions. In contrast, passive backplanes contain almost no computing circuitry.

Referring again to FIG. 4, the backplane 32 includes a connector interface 55 that facilitates the physical and electrical connection of the server units 12 to external resources. In the illustrated embodiment, the connector interface 55 facilitates “blind mating” between the backplane 32 and the server units 12. That is, the server units 12 need only make connection with the backplane 32 to have access to a power supply 58, and all network and external physical resources. Moreover, “blind mating” refers to the process of coupling the server units 12 with the backplane 32 without a user needing to visualize the back of the server units 12 and the backplane 32 during the installation process to ensure that delicate interface connections are not damaged.

To facilitate the blind mating process, the backplane 32 includes gross alignment pins 56 that mate with corresponding apertures in the back of the server unit 12, but only when the server unit 12 is properly aligned in the rack 24. In the illustrated embodiment, the gross alignment pins 56 are used in combination with server units 12 that are 2 U in height. In other embodiments, the gross alignment pins 56 may be used to align server units 12 having heights other than 2 U. In the illustrated embodiment, the gross alignment pins 56 extend outwardly from the backplane 32 further than other backplane components. The gross alignment pins 56, because of the distance the pins 56 extend outwardly from the backplane 32, are the first point of contact between a server unit 12 and the backplane 32 as the server unit 12 slides into the rack 24. The gross alignment pins 56, therefore, act as barriers that prevent the more delicate interface connections that lie behind the gross alignment pins 56 from being damaged during the insertion of a server unit 12 into the rack 24. Only after the apertures in the back of the server unit 12 align with the gross alignment pins 56 can the server unit 12 be guided further into the rack 24 towards the more delicate components of the backplane 32.

To further facilitate the blind mating process, in another embodiment, the backplane 32 also includes fine alignment pins 57 that serve the same function and operate in the same way as the gross alignment pins 56. The fine alignment pins 57 extend outwardly from the backplane 32 a shorter distance than the gross alignment pins 56, but further than the delicate interface connections of the backplane 32. Only after the server unit 12 is aligned with the gross alignment pins 56 and the fine alignment pins 57 can the server unit 12 be guided further into the rack 24 to establish the physical and electrical connections with the backplane 32.

Referring to FIGS. 5-6, mounting latches 60 in accordance with one embodiment of the invention are illustrated which further facilitate the blind mating process. The latches 60 also help prevent the server units 12 from moving once they are installed into the rack 24. In the illustrated embodiment, the mounting latches 60 are used in combination with server units 12 that are each 2 U in height. In other embodiments, the mounting latches 60 may be used with server units 12 with a height other than 2 U. A pair of mounting latches 60 are used to firmly secure each server unit 12 to the rack 24 and the cabinet 10. For purposes of illustration, only the mounting latch 60 that secures to the right front rail 17 is described, since the mounting latch 60 that secures to the left front rail 16 is a mirror image of the mounting latch 60 that secures to the right front rail 17.

In one embodiment, the body of the mounting latch 60 includes a bracket 64 that secures to the server unit 12. The body of the mounting latch 60 also includes a pivoting member 66 that pivots relative to the bracket 64 and the server unit 12. In other embodiments, the pivoting member 66 may be pivotally coupled directly to the server unit 12 without the use of a bracket 64. In yet another embodiment, the bracket 64 and the pivoting member 66 may be integrally formed and pivotally coupled to the server unit 12.

In the illustrated embodiment, the bracket 64 is generally “U” shaped, but may be any desired shape. The bracket 64 may be secured to the server unit 12 by, for example, screws, or may alternatively clip or snap onto the server unit 12. In general, any technique known in the art may be used to secure the bracket 64 to the server unit 12. In the illustrated embodiment, the bracket 64 secures to a front face 68 of the server unit 12. In other embodiments, the bracket 64 may secure another location of the server unit 12. The bracket 64 may be made, for example, from 1030 steel in a casting process, or by machining.

The pivoting member 66 of the mounting latch 60 is generally rectangular and includes an upper end 72, a lower end 74, two side surfaces 76, 78, a back surface 80, and a front surface 82. The pivoting member 66 may be made of any suitable material, including plastics or metals or any combination of materials desired. In the illustrated embodiment, the pivoting member 66 is made from an Acrylonitrile Butadiene Styrene (ABS) plastic in an injection molding operation. A pivot pin 86 that is inserted in an aperture 84 pivotally secures the bracket 64 with the pivoting member 66.

The side surface 78 of the pivoting member 66 includes one or more protrusions (not shown) that mate with corresponding dimples 83 on the bracket 64. When the pivoting member is in a “closed position” as illustrated in FIG. 6, the protrusions mate with the dimples and prevent the pivoting member 66 from inadvertently pivoting relative to the bracket 64. This ensures that the server unit 12 does not accidentally become detached from the rack 24. It will be appreciated that in other embodiments, a mating system other than dimples and protrusions may be utilized to prevent the pivoting member 66 from inadvertently pivoting relative to the bracket 64.

Also disposed between the side surface 78 of the pivoting member 66 and the bracket 64 is a torsional spring (not shown) that biases the pivoting member 66 into an “open position” as illustrated in FIG. 5. When the pivoting member 66 is in the open position, if the server unit 12 is rapidly inserted into the rack 24, the lower end 74 of the pivoting member 66 acts as a bumper and collides with the flange 34. The collision prevents the server unit 12 from proceeding further into the rack 24 towards the gross alignment pins 56. By acting as a bumper, the pivoting member 66 prevents damage to the delicate interface connections on the server unit 12 and the backplane 32.

At its upper end 72, the pivoting member 66 includes a fastener 92 that secures to both the rack 24 and the front rail 17. The fastener 92 is received in a second aperture that extends from the front surface 82 of the pivoting member 66 to the back surface 80 of the pivoting member 66. The fastener 92, for instance, may be a screw that secures to the front rail 17 by hand or with a tool. In alternative embodiments, the fastener 92 may be a ¼ turn fastener, or a fastener that enables the pivoting member 66 to snap securely into the front rail 17.

Referring to FIGS. 2-6, the steps required to secure a server unit 12 into the rack 24 and cabinet 10 are described. As a first step, a user slides the server unit 12 onto the horizontal plate 54 or the mounting rails 50 and then slides the server unit 12 further toward the backplane 32 of the rack 24. With respect to a server unit that is 2 U in height, as the server unit 12 slides further into the rack 24, the server unit 12 contacts the gross alignment pins 56. The server unit 12 is then delicately slid over the gross alignment pins 56 such that the gross alignment pins 56 are received within apertures located on the back surface of the server unit 12. Locating the gross alignment pins 56 within the apertures disposed on the back surface of the server unit 12 further aligns the server unit 12 with respect to the backplane 32. In the next step, to further align the server unit 12 with the backplane 32, the server unit 12 is similarly slid over the fine alignment pins 57.

As the server unit 12 is guided further into the rack 24, a hook 88 of the pivoting member 66 comes into close proximity to the guide/stop pin 27 mounted on the rack 24. As illustrated in FIG. 5 by arrow 100, the hook 88 of the pivoting member 66 may then be rotated upwardly over the guide/stop pin 27 to further align the server unit 12 with the backplane 32 of the rack 24. When the pivoting member 66 is in the closed position as illustrated in FIG. 6, the server unit 12 is properly seated in the rack 24, and the server unit 12 is connected to the backplane 32. Moreover, in the closed position, the protrusions on the side surface 78 of the pivoting member 66 mate with the dimples 83 on the bracket 64 and prevent the pivoting member 66 from inadvertently pivoting relative to the bracket 64. Also in the closed position, the fastener 92 passes through an aperture 36 located on the flange 34 of the rack 24 and an aperture 22 located in the front rail 17 of the cabinet 10. In this position, the fastener 92 may be secured to the front rail 17 using cage nuts.

By securing the server unit 12 to the front rails 16, 17 and not just the rack 24, the server unit 12 is more securely mounted in the cabinet 10. This is an important advantage of the current invention over prior art devices, which do not directly secure server units to the cabinet. As mentioned, securing the server unit 12 to the rack 24 alone may lead to the failure of the server unit 12 or backplane 32 over time. For instance, inadvertent movement of the server unit 12 in relation to the backplane 32 can damage the sensitive interface connections (such as the electrical connections) on either the server unit 12 or the backplane 32, and result in the failure of either of these components.

An added benefit of the mounting latches 60 is that they enable server units 12 to be quickly removed from the rack 24 to allow the rapid replacement of a server unit 12, for example, in the event a server unit 12 requires repair. For instance, a user can release the fastener 92 of the pivoting member 66 from the front rail 17, and then rotate the pivoting member 66 outward. Once the pivoting member 66 reaches an open position as illustrated in FIG. 5, the server unit 12 can be disengaged from the backplane 32, and pulled out of the rack 24 using the horizontal plates 54 as guides.

Referring to FIGS. 7A-7J, a cover plate system 110 is illustrated in accordance with another embodiment of the invention. The cover plate system 110 includes a plurality of cover plates 112 that may be 1 U in height (FIG. 7H), 2 U in height (FIG. 7A), or any other desired height. The cover plates 112 are mounted to the front rails 16, 17 of the cabinet 14 or to the flanges 34 of the rack 24 once the server units 12 are inserted into the rack 24. The cover plates 112 provide a modular look to the rack-mounted computer system and may be used to alter the airflow around the server units 12.

Each cover plate 112 includes a perforated portion 113 with end caps 115 secured to each end of the perforated portion 113. The perforated portion 113, via a plurality of holes 117, allows air to enter the rack 24 to cool the system. In the illustrated embodiment, the holes are 0.175″ in diameter and provide sufficient airflow for front end cooling of the server units 12. In other embodiments, the diameter of the holes 117 may differ. The holes 117 are staggered to minimize visualization of the components that lie behind the cover plates 112, such as the server units 12 and the rack 24. In another embodiment, elongated slits 146 may be used to promote airflow rather than circular holes (FIGS. 8A-8B). In yet another embodiment, the perforated portion 113 allows over 50% unrestricted airflow through the cover plate 112. The perforated portion 113 may be made from a metal, or any other material desired, such as a plastic. In one embodiment, the perforated portion 113 is made from aluminum to maintain the structural integrity of the perforated portion 113 while reducing the weight of the cover plate 112.

Referring to FIG. 7H, in another embodiment, instead of including a perforated portion 113 that enables airflow through the cover plate 112, the cover plate 112 supports a simulated perforated metal face 124 which blocks airflow (i.e. a face that looks that it is perforated, but is actually without holes). These cover plates 112 are used to cover empty slots 11 of the rack 24 (i.e. slots 11 that are not loaded with server units 12) to block airflow to the empty slots 11. By blocking airflow to the empty slots 11, air may be more efficiently directed to cool the server units 12.

The end caps 1 15 situated on each side of the perforated portion 113 may be made from metal, or any other material desired, such as plastic. In one embodiment, the end caps 115 are made from an extruded plastic such as ABS. The end caps 115 may include system information, logos, LED ports, and nomenclature of operation. For example, in the illustrated embodiment, the end caps 115 include a plurality of guide holes 119 that act as locators for light pipes (not shown). The light pipes extend from the server units 12 to the cover plates 112, and funnel LED light functions to the cover plate 112 where they can be visualized by a user. The number of light pipes and the number of guide holes 119 can be adjusted to match the number of LED's on the server units 12.

In addition to including the guide holes 119, the end caps 115 also include a gripping surface 120 to facilitate the handling of a cover plate 112. For example, in the illustrated embodiment, the gripping surface 120 includes a pocketed area 120 on each end cap 115. In other embodiments, however, a different gripping surface 120, such as a knob may be utilized.

As mentioned, the cover plates 112 may be secured to either the front rails 16, 17 or the rack 24. As an example, to secure a cover plate 112 to the rack-mounted computer system, two ball studs that are disposed on the back of each 1 U or 2 U cover plate 112 may snap into sockets located on the front rails 16, 17 or the flanges 34 of the rack 24. It will be appreciated that in other embodiments, different fastening systems may be used to secure the cover plates 112, for instance screws with mating wing nuts.

Referring to FIG. 7G, in another embodiment, multiple cover plates 112 are assembled on a backer plate 114 and then the backer plate 114 is secured to the front rails 16, 17 or the flanges 34 of the rack 24. The backer plate 114 may be any height desired, for instance 10 U as illustrated. Use of a backer plate 114 simplifies the handling of multiple cover plates 112 and reduces the amount of ball and stud mounting required to individually secure the cover plates 112 to the cabinet 10 or rack 24. A further advantage of using the backer plate 114 is that the backer plate 114 provides an area of additional airflow control at a more direct point in front of the individual server units 12. This allows critical airflow deviations to be addressed at a location nearest to the server units 12. For instance, baffles (not shown) may be coupled to the backer plate 114 to channel air to locations that require cooling.

Referring to FIG. 7G, the backer plate 114 includes a plurality of ball studs 116 that mate with corresponding sockets (not shown) that are disposed on the back of each cover plate 112. In other embodiments, an alternative fastening mechanism may be used to secure the cover plates 112 to the backer plate 114. After the cover plates 112 are coupled to the backer plate 114, the backer plate 114 may be coupled to the system by pushing sockets 118 disposed on the backer plate 114 onto ball studs (not shown) that are disposed on the rack 24 or the front rails 16, 17.

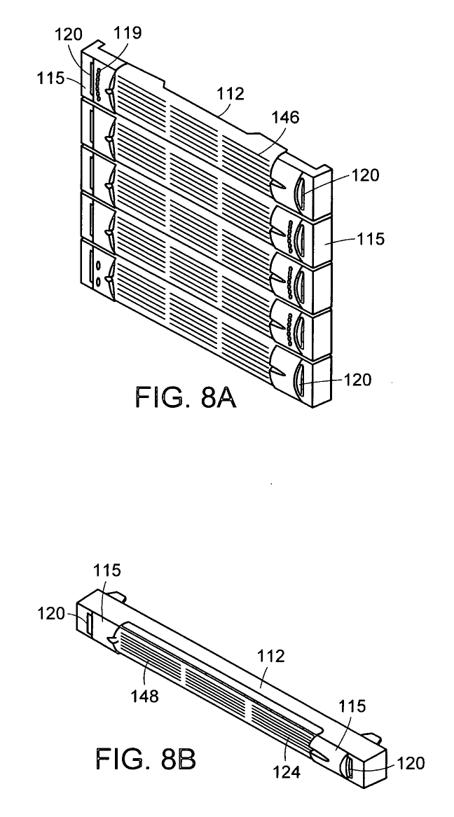

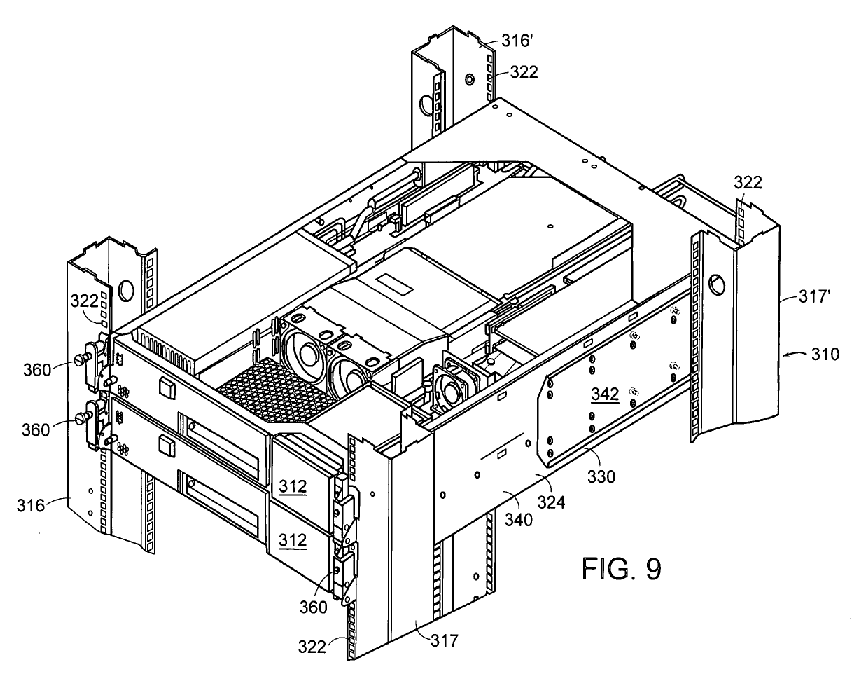

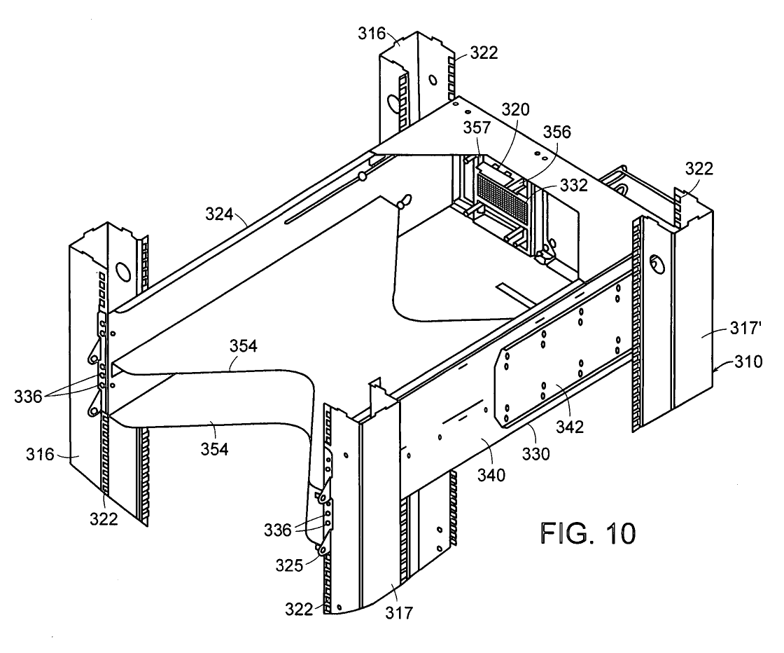

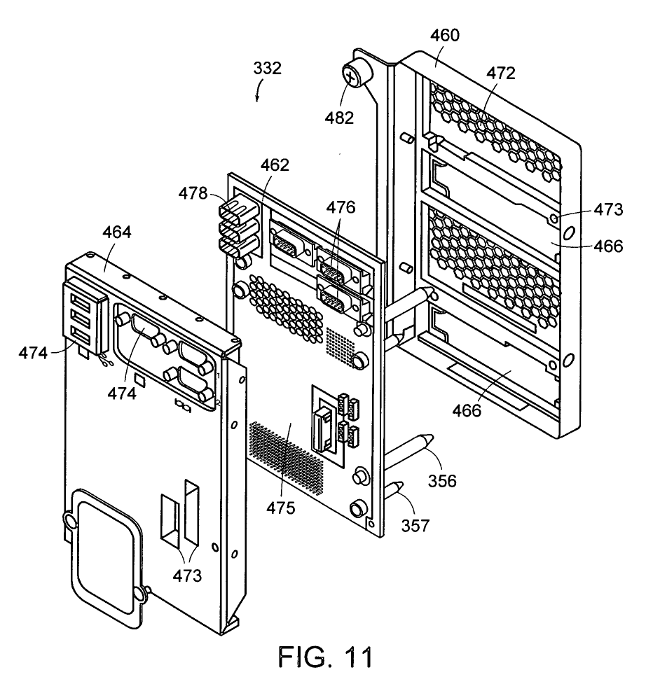

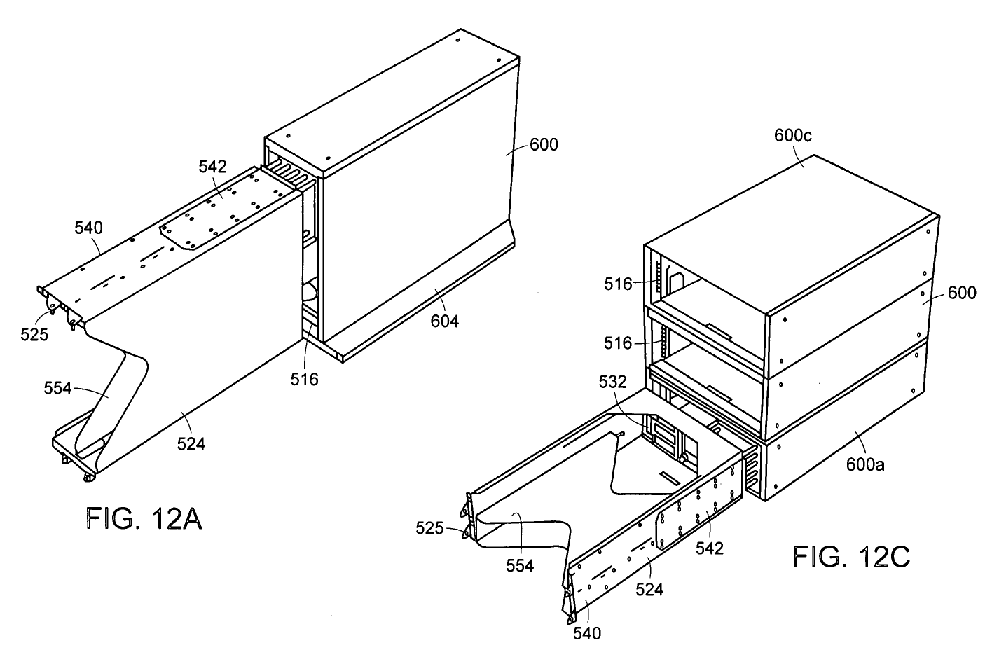

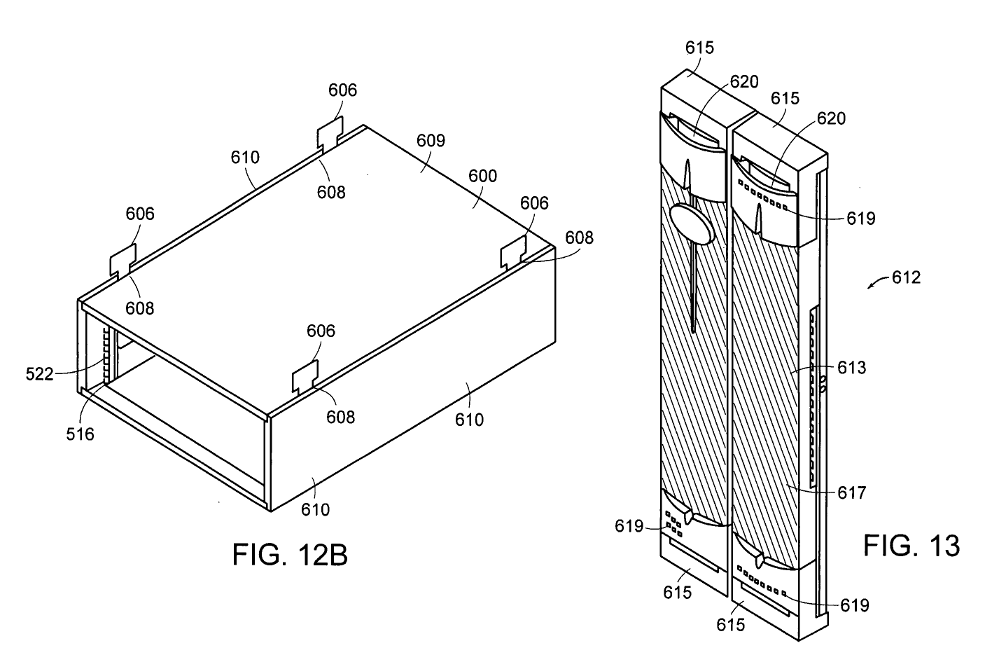

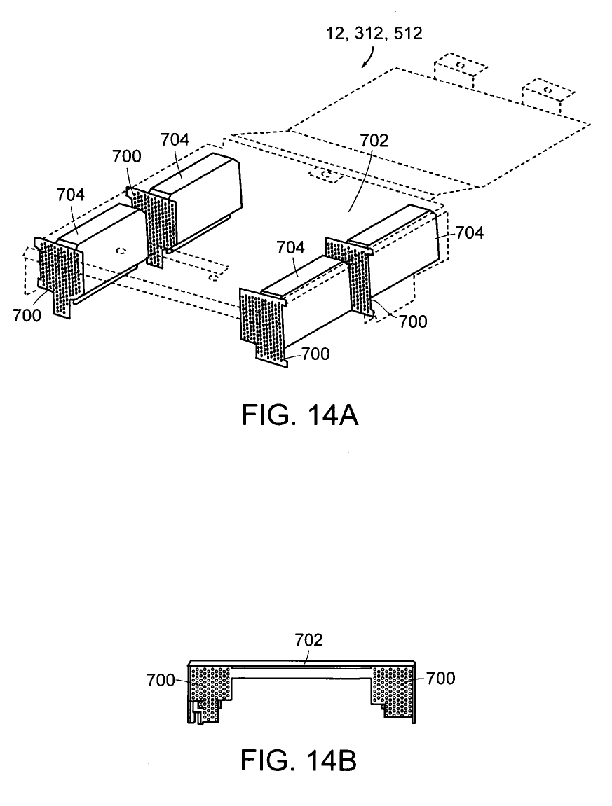

Referring to FIG. 71, an alternative embodiment for coupling a cover plate 112 to the rails 16, 17 is illustrated. In the illustrated embodiment, a mounting clip 128 is included on a back surface 129 of the cover plate 112 at each end cap 115. In one embodiment, the mounting clip 128 includes a body portion 130 and the body portion 130 includes two apertures that receive screws 134 to couple the mounting clip 128 to the cover plate 112. In another embodiment, a different fastening mechanism, for instance, a snap fit may be used to secure the mounting clip 128 to the cover plate 112. Coupled to the body portion 130 are three springs 136a, 136b and 136c (generally, 136). In alternative embodiments, a different number of springs 136, for example, two springs or four springs, may be coupled to the body portion 130. The springs 136 can be made from a half hard steel, with memory built into the metal. Alternatively, a plastic, such as nylon available from E.I. duPont de Nemours & Co., Wilmington, Del., could be used to form the spring. Each spring 136 extends longitudinally from the body portion 130, and has a curved finger 138 at its end. The springs 136a, 136b, and 136c are each rotated relative to the body portion 130, such that each spring has a different orientation. For instance, spring 136a points downwards, spring 136b points inwards, and spring 136c points upwards.

Referring to FIGS. 71-7J, to secure a cover plate 112 that includes a pair of mounting clips 128 to the front rails 16, 17 of the cabinet 10 (shown in phantom in FIG. 71 as rail 17), each spring 136a, 136b, 136c is aligned with a different aperture 22 in the front rail 17, and guided through its respective aperture 22. As the spring 136a is guided through an aperture 22, the spring 136a deflects downwardly. Similarly, the spring 136b deflects inwardly, and the spring 136c deflects upwardly. Once the fingers 138 of the springs 136 are through the apertures 22, the springs 136 return to their positions prior to deflection and each finger 138 couples with a back surface 142 of the front rail 17.

One advantage of having three springs 136 with each spring 136 having a different orientation with respect to the body 130 is that motion of the cover plate 112 is constrained both vertically and horizontally when mounted to the rails 16, 17. For instance, as shown in FIG. 7J, the cover plate 112 is prevented from moving vertically when secured to the front rail 17 by springs 136a and 136c. Similarly, motion of the cover plate 112 in a horizontal direction is prevented by the spring 13 6b located on each end cap 115.

Another advantage of the mounting clip 128 is that the mounting clip couples to front rails 16, 17 with square or rounded apertures 22 (a front rail 17 with rounded apertures 22 is shown in phantom in FIG. 71). The ability of the mounting clip 128 to mount to front rails 16, 17 having different aperture configurations eliminates the need to supply multiple mounting options for similar type designs. The mounting clip 128 is also beneficial, since its use eliminates the cumbersome assembly of nut clips and loose hardware to attach system components to the front rails 16, 17.

Referring to FIGS. 9-10, an alternative embodiment of a rack-mounted computer system is illustrated. The system is similar to the system earlier described in FIGS. 1-3, and may include all of the described guide features to achieve blind mating of the server units 312 with the backplane 332. However, the rack-mounted computer of the present embodiment is 4 U in height rather than 10 U. Further, rather than the I/O boards being separate from the CPU boards as in the system earlier described, in the illustrated embodiment, the I/O functions and the CPU are combined on a single server unit 312.

With reference to FIG. 11, the backplane 332 for use with the system of FIGS. 9-10 is described in greater detail. In general, the backplane 332 provides the same functionality as the backplane 32 described earlier. However, in the illustrated embodiment, a single backplane 332 acts as the interconnect between the CPU, the clock card, the MUX card, and the modem which reduces the mounting requirements that would be necessary if each card was provided separately. The illustrated backplane 332 is 4 U in height, and therefore may connect with two 2 U server units 312 as illustrated in FIG. 9.

Referring to FIG. 11, the sandwich-like construction of the backplane 332 is illustrated. As shown, the backplane 332 includes a server facing portion 460, a PCB board 462, and an external facing portion 464 that are secured together by fasteners. The external facing portion 464 and the server facing portion 460 may be made from aluminum, or any other suitable material. The server facing portion 460 has a plurality of slots 466 that accept the delicate interface connections that protrude from the PCB 462. The interface connections mate with the back of the server units 312 when the server units 312 are installed into the rack 324. Also included on the server facing portion 460 of the backplane 332 are a plurality of apertures 472 that enable air to enter the interior of the backplane 332 to cool the PCB during operation of the computer system. Further, generally circular apertures 473 are disposed in the server facing portion 460 that enable the gross alignment pins 356 to extend through the server facing portion 460 (the fine alignment pins 357 extend through the slots 466). As described earlier, the gross alignment pins 356 and the fine alignment pins 357 help the blind mating of the server units 312 with the PCB 462 of the backplane 332.

The external facing portion 464 of the backplane 332 includes a plurality of slots 474 that interface with an external facing surface 475 of the PCB 462. For instance, the external facing surface 475 of the illustrated PCB 462 includes serial ports 476 and USB ports 478 that extend through the apertures 474 when the PCB 462 is assembled with the server facing portion 460 and the external facing portion 464 of the backplane 332. In another embodiment, a modem may be attached to the external facing portion 464 and connect with the PCB 462 upon assembly of the backplane 332.

With reference to FIGS. 10-11, once the backplane 332 is assembled, the backplane 332 may be secured to the rack 324. More specifically, the backplane 332 is guided into position at the rear of the rack 324, and fasteners 482 disposed on the server facing portion 460 of the backplane 332 are used to firmly secure the backplane 332 to the rack 324. The illustrated fastening system is one method of securing the backplane 332 to the rack 324, and should in no way be considered limiting.

One advantage of the modular construction of the backplane 332 described above is that the backplanes 332 may be customized to match the I/O and CPU components on the server unit 312. For example, if an I/O system is added to the server unit 312, the backplane 332 may be replaced with the appropriate backplane 332 that includes the required connections to the new I/O system.

Referring to FIGS. 12A-12C, an alternative embodiment of a rack-mounted computer system is illustrated. The system functions like the rack-mounted computer systems described earlier. However, rather than the rack being mounted horizontally to the rails as in the earlier embodiments, the rack 524 is mounted vertically in a pedestal enclosure 600 (FIG. 12A). To accommodate the vertical mounting of the rack 524, the rails 516, 517, 516′, 517′ are disposed horizontally in the pedestal enclosure 600.

The pedestal enclosure 600 of the current embodiment is designed to be low profile such that it may fit beneath a desk. Additionally, the pedestal 600 includes casters 602 that enable the pedestal enclosure 600 to be easily moved. An anti-tip structure 604 may be included to support the pedestal enclosure 600 in its vertical orientation. The pedestal enclosure 600 may be formed from aluminum, or any other material that does not deform when the rack 524 and the server units 512 are mounted in the enclosure 600.

Referring to FIGS. 12A-12C, one advantage of the pedestal enclosure 600 is that the casters 602 and anti-tip structure 604 may be removed to enable the pedestal enclosure 600 to lie horizontally. In its horizontal orientation, the pedestal enclosure 600 may rest, for instance, on a desk. In one embodiment in accordance with the invention, multiple pedestal enclosures may be horizontally stacked as illustrated in FIG. 12C. Referring to FIG. 12B, to facilitate the horizontal stacking of pedestal enclosures 600, support brackets 606 made, for instance, from aluminum may be inserted into slots 608 that are disposed between an upper surface 609 and a sidewall 610 of the pedestal enclosure 600. Referring to FIG. 12C, when a second pedestal enclosure 600b is stacked on the pedestal enclosure 600a that includes the brackets 606, the portion of the support brackets 606 that protrude vertically from the pedestal enclosure 600a are inserted into mating slots disposed in the bottom of the pedestal enclosure 600b. When the support brackets 606 are inserted into the slots on both pedestal enclosures 606a, 606b, pedestal enclosure 606b is prevented from sliding horizontally relative to pedestal enclosure 606a. In other embodiments, different fastening systems, for instance a hook and loop fastening system, may be used to prevent the stacked pedestal units 600 from sliding relative to each other.

With reference to FIG. 13, the pedestal enclosure 600 can also be provided with cover plates 612 that are substantially identical to the cover plates described earlier in FIGS. 7A-7J. The cover plates 612 of the illustrated embodiment, however, are designed for attachment to pedestal enclosures 600 that are stored vertically (i.e. like the pedestal enclosure 600 illustrated in FIG. 12A).

Referring to FIGS. 14A-14B, in another embodiment according to the invention, baffle blockers 700 may be placed within the server units 12, 312, 512 to regulate airflow within the server units 12, 312, 512. The baffle blockers 700 may be made from plastic, metal, or any other desired material and can be secured to plenum walls 702, which typically surround voltage regulation modules 704 and central processing units (not shown) that are disposed in the interior of the server units 12. More specifically, with reference to FIG. 14A in which the plenum walls 702 are shown in phantom, the baffle blockers 700 may snap into slots disposed in the plenum walls 702 at locations in front of the voltage regulation modules 704 to control the airflow to the voltage regulation modules 704. In alternative embodiments, the baffle blockers 700 may be secured to the plenum walls 702 using, for instance, fasteners such as screws, or glue.

Each baffle blocker 700 includes a plurality of staggered holes, and the layout of the staggered holes, along with the size and number of staggered holes at least partially defines the amount of air that passes through each baffle blocker 700 to the voltage regulation module 704. In addition, the shape of the baffle blocker 700 itself may affect the amount of air that bypasses the baffle blocker 700 to cool the voltage regulation module 704. In general, the strategic selection and placement of baffle blockers 700 may be used to more accurately and precisely control the airflow around the voltage regulation module and central processing units.

The invention may be embodied in other specific forms without departing form the spirit or essential characteristics thereof. The foregoing embodiments are therefore considered in all respects illustrative rather than limiting of the invention described herein. Scope of the invention is thus indicated by the appended claims rather than by the foregoing description, and all changes which come within the meaning and range of equivalency of the claims are therefore intended to be embraced herein.

What is claimed is:

1. A system for mounting a server unit comprising:
a cabinet comprising a plurality of rails;
a rack for receiving the server unit, the rack couplable to the rails; and
a mounting latch pivotally couplable to the server unit, the mounting latch comprising a fastener securable to a rail.

2. The system of claim 1, wherein the rack further comprises a plurality of guides for aligning the server unit in the rack.

3. The system of claim 1, wherein the mounting latch comprises a spring that biases an end of the mounting latch towards a front surface of the rack, the end acting as a bumper.

4. The system of claim 2, wherein the plurality of guides comprise pins.

5. The system of claim 1, wherein the plurality of rails comprise front and rear rails, wherein the front rails are longitudinally spaced from the rear rails.

6. The system of claim 1, wherein the rack further comprises adjustable sidewalls.

7. The system of claim 1, wherein a curved surface of the mounting latch engages a pin disposed on a front surface of the rack.

8. The system of claim 2, wherein the plurality of guides comprise a horizontal plate disposed between sidewalls of the rack.

9. A mounting clip for securing a component into a rail comprising:
a body;
a first, second, and third spring extending longitudinally from the body, the first, second, and third spring each comprising a curved portion;
the first spring oriented in a first direction relative to the body,
the second spring oriented in a second direction relative to the body; and
the third spring oriented in a third direction relative to the body, wherein the mounting clip when secured to the rail prevents motion of the component horizontally and vertically.

10. A mounting latch for fastening a server unit to a cabinet rail comprising:
a body pivotally couplable to a server unit, wherein the body comprises a fastener engageable with the cabinet rail.

11. The mounting latch of claim 10, wherein the body further comprises a curved surface rotatably engageable with a rack, the rack couplable to the cabinet rail.

12. The mounting latch of claim 10, wherein the fastener comprises a threaded portion for engaging the cabinet rail.

13. The mounting latch of claim 10, wherein the fastener comprises a slotted head for receiving a tool.

14. The mounting latch of claim 10, wherein the body further comprises a pivoting member and a bracket couplable to the server unit.

15. The mounting latch of claim 14, wherein the body further comprises a locking member disposed between the pivoting member and the bracket to prevent the pivoting member from rotating relative to the server unit.

16. The mounting latch of claim 15, wherein the locking member comprises a protrusion disposed on the pivoting member for mating with a groove disposed in the bracket.

17. The mounting latch of claim 15, wherein the locking member comprises a groove disposed in the pivoting member for mating with a protrusion disposed on the bracket.

18. The mounting latch of claim 10 further comprising a spring to bias an end of the mounting latch towards a front surface of a rack, the end of the mounting latch acting as a bumper.
